(19) United States
(12) Patent Application Publication
(10) Pub. No.: US 2018/0137918 A1
(43) Pub. Date: May 17, 2018

(54) METHOD FOR OPERATING MEMORY ARRAY

(71) Applicant: MACRONIX INTERNATIONAL CO., LTD., Hsinchu (TW)

(72) Inventors: Guan-Wei Wu, Kaohsiung County (TW); Yao-Wen Chang, Hsinchu City (TW); I-Chen Yang, Changhua City (TW)

(21) Appl. No.: 15/350,157

(22) Filed: Nov. 14, 2016

(51) Int. Cl. G11C 16/14; G11C 16/04; H01L 27/115; H01L 29/792; H01L 29/423

(52) U.S. Cl. CPC G11C 16/14; G11C 16/0466; H01L 29/42392; H01L 27/11582; H01L 29/7926; G11C 16/0483

(57) ABSTRACT

“A method for operating a memory array includes an all programming step, an erasing step and a selectively programming step. The all programming step is to program all of memory cells of a NAND string. The erasing step is to erase the all of the memory cells of the string after the all programming step. The selectively programming step is to program a portion of the all of memory cells of the NAND string after the erasing step. The NAND string includes a pillar channel layer, a pillar memory layer and control gates. The pillar memory layer is surrounded by the control gates separated from each other. The memory cells are defined at intersections of the pillar channel layer and the control gates.”

### BACKGROUND

### Technical Field

The disclosure relates to a method for operating a memory array, and particularly to a method for operating a memory array for improving device stability.

### Description of the Related Art

As critical dimensions of devices in integrated circuits shrink toward perceived limits of manufacturing technologies, designers have been looking to techniques to achieve greater storage capacity, and to achieve lower costs per bit. Technologies being pursued include a 3D (three-dimensional) NAND memory having multiple layers of memory cells on a single chip and operations performed therefor. However, current memory arrays have unstable data storage problems.

### SUMMARY

The present disclosure relates to a method for operating a memory array.

According to an embodiment, a method for operating a memory array is disclosed. The method comprises an all programming step, an erasing step and a selectively programming step. The all programming step is performed to program all of memory cells of a NAND string. After the all programming step, the erasing step is performed to erase the all of the memory cells of the NAND string. After the erasing step, the selectively programming step is performed to program a portion of the all of memory cells of the NAND string. The NAND string comprises a pillar channel layer, a pillar memory layer and control gates. The pillar memory layer is surrounded by the control gates separated from each other. The memory cells are defined at intersections of the pillar channel layer and the control gates.

According to an embodiment, a method for operating a memory array is disclosed. The method comprises an all programming step, an erasing step and a selectively programming step. The all programming step is performed to program at least three adjacent memory cells sharing a memory layer. Then, the erasing step is performed to erase the at least three adjacent memory cells. Then, the selectively programming step is performed to program only a portion of the at least three adjacent memory cells.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 is a three dimensional view of a portion of a memory structure of a NAND string of a memory array according to an embodiment.

FIG. 2 illustrates a cross-section view of the memory structure along AA line in FIG. 1.

FIG. 3 is a schematic drawing showing a memory structure operated with a method according to an embodiment.

FIG. 4 is a schematic drawing showing a memory structure operated with a method according to a comparative example.

FIG. 5 shows curves of a relation between a retention time and a threshold voltage of an embodiment and a comparative example.

FIG. 6 is an operation method flow according to an embodiment.

FIG. 7 is an operation method flow according to an embodiment.

### DETAILED DESCRIPTION

Embodiments disclosed herein relate to a method for operating a memory array which can improve stability for a memory device.

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

In embodiments, all of memory cells sharing a memory layer of a memory structure are programmed before being erased. By which, after a portion of the all of the erased memory cells is selected to be programmed, Vt deviation between the selected memory cells in the programmed stated and the unselected memory cells maintained in the erased state can be reduced to improve stability of electrical characteristics and data storage. The concept of the present disclosure is illustrated by the following embodiments, but not limited thereto.

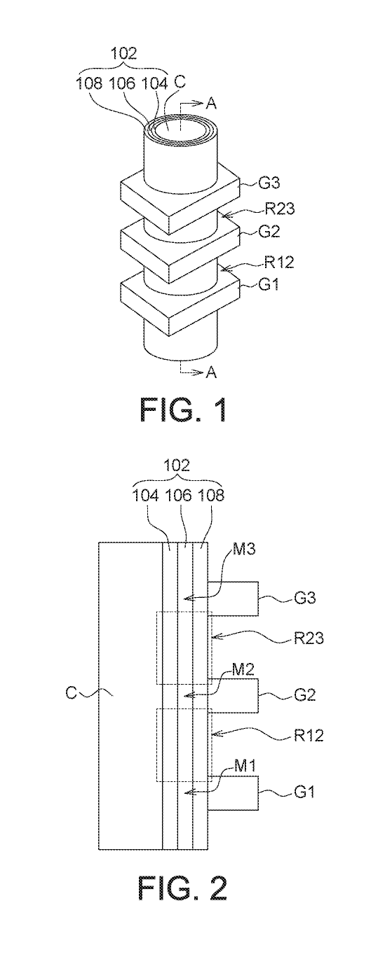

FIG. 1 is a three dimensional view of a portion of a memory structure of a NAND string of a memory array according to an embodiment. The NADN string comprises a channel layer C, control gates G1, G2, G3 and a memory layer 102 between the channel layer C and the control gates G1, G2, G3. The memory layer 102 comprises a charge trapping film 106. The charge trapping film 106 may be between the tunneling dielectric layer 104 and the blocking dielectric layer 108. In the embodiment, the charge trapping film 106 is a nitride (i.e. a nitride charge trapping film), such as silicon nitride. The tunneling dielectric layer 104 and the blocking dielectric layer 108 are an oxide such as silicon oxide. In other words, the memory layer 102 has an oxide-nitride-oxide (ONO) structure. The channel layer C may comprise a Poly-silicon material, etc. for example.

In the embodiment, the NAND string comprises a memory structure having a gate-all-around (GAA) structure. As shown in FIG. 1, the channel layer C is a pillar channel layer. The memory layer 102 is a pillar memory layer, which may be regarded as an annular or hollow pillar memory layer surrounding the channel layer C. The control gates G1, G2, G3 surrounding the memory layer 102 can be functioned as word lines. Memory cells (for example M1, M2, M3 in FIGS. 2 to 4) are defined at cross-points between the channel layer C and the control gates G1, G2, G3. The control gates G1, G2, G3 may be spaced apart from each other by an insulating layer disposed in regions corresponding to regions R12, R23 between the control gates G1, G2, G3.

In embodiments, in a method for operating the NAND string, all of the memory cells are programmed and then are directly erased. The term “directly” in the present disclosure means no additional step is performed between the said two steps. In other words, there is no additional step performed between the programming step to the all of the memory cells and the erasing step to the all of the memory cells. A method for the programming step may comprise providing a programming bias to the memory structure. A method for the erasing step may comprise providing an erasing bias opposing to the programming bias to the memory structure.

FIG. 2 illustrates a cross-section view of the memory structure along AA line in FIG. 1. In an embodiment, the memory cells M1, M2, M3 are programmed by a method comprising providing the programming bias to the control gates G1, G2, G3. The programming bias is a positive voltage. In an embodiment, the programming bias provided to the control gates G1 G2, G3 is the positive voltage (such as 20V), which could induce electrons (negative charges) into the charge trapping film 106 from the channel layer C. In the present disclosure, the programming step to the all of the memory structure/memory cells can be referred to as a term of “all programming step” and/or indicated with a symbol of “ALL PGM”. The all of the memory structure/memory cells may be programmed simultaneously. For example, the programming method may be carried out through FN tunneling mechanism.

In embodiments, after the memory cells M1, M2, M3 are programmed, the programmed memory cells M1, M2, M3 are then erased. The erasing step to the memory cells M1, M2, M3 comprises providing an erasing bias to the control gates G1, G2, G3. The erasing bias is opposite to the programming bias. In an embodiment, the erasing bias provided to the control gates G1, G2, G3 are a negative bias (such as −20V), which would induce holes (positive charges) into the charge trapping film 106. In the present disclosure, the erasing step to the all of the memory structure/memory cells can be referred to as a term of “all erasing step” and/or indicated with a symbol of “ALL ERS”. The all of the memory structure/memory cells may be erased simultaneously. For example, the erasing method may be executed through FN tunneling mechanism.

After the memory cells M1, M2, M3 are erased, a portion of which may be selected to be programmed. In an embodiment, for example, the memory cell M2 is selected and programmed, while the unselected memory cells M1, M3 located at opposing sides of the memory cell M2 are maintained in the erased state. The memory cell M2 may be programmed by a method comprising providing a programming bias to the control gate G2, such as a positive voltage (such as 20V), and the control gates G1 and G3 are biased 10V, which would inject electrons into the charge trapping film 106 from the channel layer C. In the present disclosure, the programming step to only a portion of the all of the memory structure/memory cells (for example only the memory cell M2 in the memory cells M1, M2, M3) can be referred to as a term of “selectively programming step” and/or indicated with a symbol of “SPGM”. For example, the programming method may be carried out through FN tunneling mechanism.

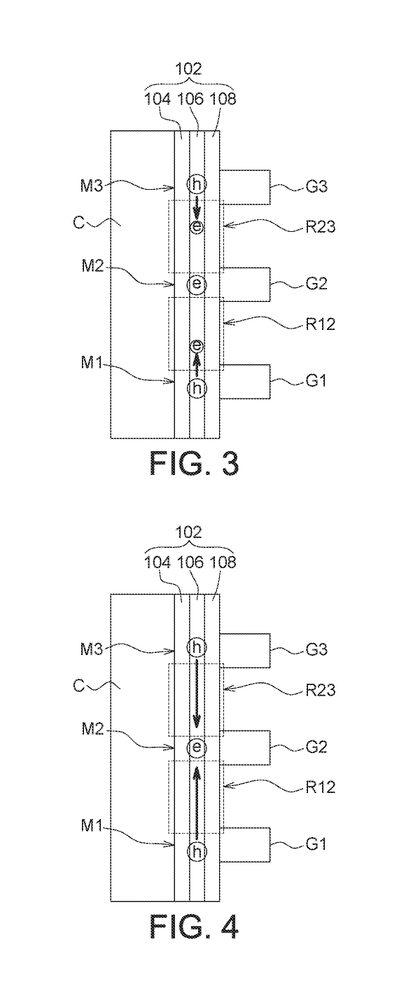

Referring to FIG. 3, in embodiments, the all programming step (ALL PGM) injects electrons into not only portions of the memory layer 102 corresponding to the control gates G1, G2, G3/memory cells M1, M2, M3, but also regions R12, R23 between the control gates G1, G2, G3/memory cells M1, M2, M3 resulted from an fringe electric field. Therefore, after the selected memory cell M2 is programmed through the selectively programming step (SPGM), the holes in the erased memory cells M1, M3 would laterally move to combine with the electrons in the regions R12, R23 prior to the electrons in the memory cell M2. Thus the storage charges in the programmed memory cell M2 would not be affected by the adjacent erased memory cells M1, M3 and have a stability characteristic.

Referring to FIG. 4, in a comparative example, there is no all programming step (ALL PGM) performed before an all erasing step (ALL ERS). Therefore, after the selected memory cell M2 is programmed by the selectively programming step (SPGM), in the regions R12, R23 there is no electrons with an amount sufficient for the holes in the erased memory cells M1, M3 to combine with to prevent the holes from moving into the memory cell M2. The holes would laterally move to combine with the electrons in the programmed memory cell M2, and affect the programmed memory cell M2 in the storage charge state and electrical characteristics such as a threshold voltage.

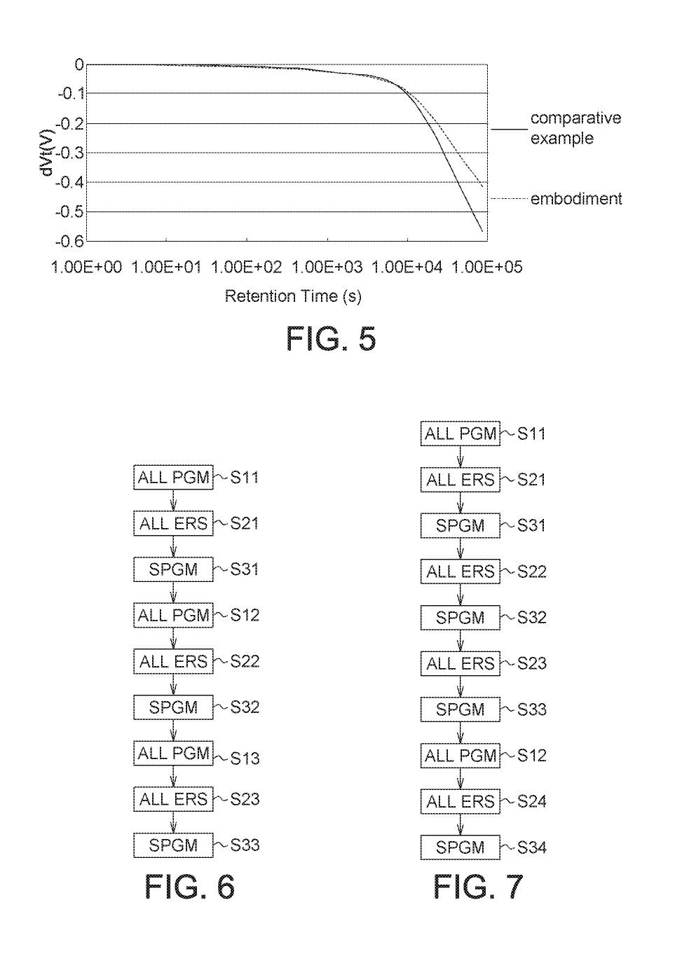

FIG. 5 shows curves of a relation between a retention time and a threshold voltage of an embodiment and a comparative example. From the result, it is proved that the operating method according to embodiments can improve stability of the device.

Although the foregoing is illustrate with a vertical NAND string with three memory cells, the concept for the operating method according to the present disclosure can be applied to various device conditions.

For example, the all erasing step (ALL ERS), the all programming step (ALL PGM) and the selectively programming step (SPGM) may be carried out at suitable timings according to actual demands.

For example, FIG. 6 illustrates an operating method for a memory structure according to an embodiment. A (first) all programming step (ALL PGM) S11, a (first) all erasing step (ALL ERS) S21, a first selectively programming step (SPGM) S31, a (second) all programming step (ALL PGM) S12, a (second) all erasing step (ALL ERS) S22, a (second) selectively programming step (SPGM) S32, a (third) all programming step (ALL PGM) 513, a (third) all erasing step (ALL ERS) S23 and a (third) selectively programming step (SPGM) S33 are executed in sequence.

In other embodiments, after the all programming step (ALL PGM) is performed one time, at least two times of the all erasing steps (ALL ERS) are performed, wherein none of the all programming step (ALL PGM) is performed between the at least two times of the all erasing steps (ALL ERS).

For example, FIG. 7 illustrates an operating method for a memory structure according to an embodiment. A (first) all programming step (ALL PGM) S11, a (first) all erasing step (ALL ERS) S21, a (first) selectively programming step (SPGM) S31, a (second) all erasing step (ALL ERS) S22, a (second) selectively programming step (SPGM) S32, a (third) all erasing step (ALL ERS) S23, a (third) selectively programming step (SPGM) S33, a (second) all programming step (ALL PGM) S12, a (fourth) all erasing step(ALL ERS) S24, and a (fourth) selectively programming step (SPGM) S34 are executed in sequence.

The NAND string may comprise any amount of the memory cells sharing the memory layer. For example, the NAND string may have an amount of the memory cells more than the three control gates G1, G2, G3 as shown in FIG. 1 by using more spaced control gates. The selectively programming step (SPGM) may be used to program at least one of inter-memory cell(s) between two memory cells at opposing end sides of the NAND string. For example, as to a case of adjacent four memory cells of a NAND string, a programming step may be performed to at least one of the two inter-memory cells, while the unselected memory cells are maintained in an erased state. As to a case of adjacent five memory cells of a NAND string, a programming step may be performed to at least one of the three inter-memory cells, while the unselected memory cells are maintained in an erased state, and so on.

The NAND string is not limited to a vertical channel memory structure. The operating method according to embodiments can also be applied to a vertical gate memory structure, or other kinds of NAND string structure comprising a memory layer shared by memory cells. The channel layer may be electrically connected to a source and a drain with opposing two ends thereof, and may be connected to a string selection gate (SSL).

The memory layer shared in the NAND string may comprise a charge trapping structure of any kind, such as an oxide-nitride-oxide (ONO) structure, or an oxide-nitride-oxide-nitride-oxide (BE-SONOS) structure, etc. For example, the charge trapping film may use a nitride such as silicon nitride, or other similar high-K materials, comprising a metal oxide such as Al₂O₃, HfO₂, etc.

The memory array comprises a plurality of NAND strings with a plurality of control gates (word lines) for commonly controlling the NAND strings. Memory cells of an array are defined at intersections of the control gates and the channel layers. In the operating method, the all erasing step (ALL ERS), the all programming step (ALL PGM) and the selectively programming step (SPGM) are performed to the memory cells of the array.

Accordingly, the operating method according to embodiments can improve stability of electrical characteristics and storage data of a memory array.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for operating a memory array, comprising:
an all programming step to program all memory cells of a NAND string, wherein the NAND string comprises:
a pillar channel layer;
a pillar memory layer; and
control gates spaced apart from each other and surrounding the pillar memory layer, the memory cells are defined at cross-points between the pillar channel layer and the control gates;
an erasing step to erase the all of the memory cells of the NAND string after the all programming step; and
a selectively programming step to program a portion of the all of memory cells of the NAND string after the erasing step.

2. The method for operating the memory array according to claim 1, wherein the erasing step is directly performed after the all programming step.

3. The method for operating the memory array according to claim 1, comprising performing the erasing step at least two times after the all programming step is performed.

4. The method for operating the memory array according to claim 1, further comprising another erasing step to erase the all of the memory cells of the NAND string, wherein the selectively programming step is between the erasing step and the another erasing step.

5. The method for operating the memory array according to claim 1, wherein the memory array comprise a plurality of the NAND strings, the all programming step is to program the all of the memory cells of the plurality of the NAND strings at the same time, and the erasing step is to erase to the all of the memory cells of the plurality of the NAND strings at the same time.

6. The method for operating the memory array according to claim 1, wherein the selectively programming step and/or the all programming step comprises providing a programming bias to the control gates, the erasing step comprises providing an erasing bias to the control gates, the programming bias is a positive voltage, the erasing bias is a negative bias.

7. The method for operating the memory array according to claim 1, further comprising another all programming step to program the all of memory cells of the NAND string after the selectively programming step.

8. The method for operating the memory array according to claim 1, wherein the pillar memory layer comprises a charge trapping film, electrons are injected into the charge trapping film through the all programming step and/or the selectively programming step, holes are injected into the charge trapping film through the erasing step.

9. The method for operating the memory array according to claim 1, wherein the pillar memory layer is an oxide-nitride-oxide (ONO) structure or an oxide-nitride-oxide-nitride-oxide (ONONO) structure, shared by the all of the memory cells of the NAND string.

10. A method for operating a memory array, comprising:
an all programming step to program at least three adjacent memory cells, wherein each of the at least three adjacent memory cells shares a memory layer;
an erasing step to erase the at least three adjacent memory cells after the all programming step; and
a selectively programming step to program only a portion of the at least three adjacent memory cells after the erasing step.

11. The method for operating the memory array according to claim 10, wherein the erasing step is directly performed after the all programming step.

12. The method for operating the memory array according to claim 10, comprising performing the erasing step at least two times after the all programming step is performed.

13. The method for operating the memory array according to claim 10, further comprising another erasing step to erase the at least three adjacent memory cells, wherein the selectively programming is to program only the middle memory cell between the other two of the at least three adjacent memory cells between the erasing step and the another erasing step.

14. The method for operating the memory array according to claim 10, wherein the all programming step and the erasing step are performed to all of memory cells of the memory array.

15. The method for operating the memory array according to claim 10, wherein the selectively programming step and/or the all programming step comprises providing a programming bias to a memory structure comprising the at least three adjacent memory cells, the erasing step comprises providing an erasing bias to the memory structure comprising the at least three adjacent memory cells, the programming bias is a positive voltage, the erasing bias is a negative bias.

16. The method for operating the memory array according to claim 10, wherein the memory layer at least comprises a charge trapping film shared by the at least three adjacent memory cells.

17. The method for operating the memory array according to claim 10, wherein the selectively programming step is to program the middle memory cell between the other two of the at least three adjacent memory cells.

18. The method for operating the memory array according to claim 10, wherein the memory array comprises a memory structure having a gate-all-around (GAA) structure.

19. The method for operating the memory array according to claim 10, wherein the memory layer at least comprises a nitride charge trapping film shared by the at least three adjacent memory cells, electrons are injected into the nitride charge trapping film through the programming step, holes are injected into the nitride charge trapping film through the erasing step.

20. The method for operating the memory array according to claim 10, wherein the memory layer comprises an oxide-nitride-oxide (ONO) structure or an oxide-nitride-oxide-nitride-oxide (ONONO) structure, shared by the at least three adjacent memory cells.
